(19) United States
(12) Patent Application Publication
(10) Pub. No.: US 2025/0255120 A1
(43) Pub. Date: Aug. 7, 2025

(54) DISPLAY PANEL AND DISPLAY DEVICE

(71) Applicants: Chengdu BOE Optoelectronics Technology Co., Ltd., Chengdu, Sichuan (CN); BOE Technology Group Co., Ltd., Beijing (CN)

(72) Inventors: Xin ZHOU, Beijing (CN); Bin LIU, Beijing (CN); Hong LEI, Beijing (CN); Jiandong BAO, Beijing (CN); Chuanwu MOU, Beijing (CN); Xiaodong CONG, Beijing (CN); Yunhao WANG, Beijing (CN); Qing WANG, Beijing (CN); Shuo LI, Beijing (CN); Zhenglong YAN, Beijing (CN); Shan LIU, Beijing (CN); Xiaoge WANG, Beijing (CN); Zifeng WANG, Beijing (CN); Zongqiu HANG, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/856,884

(22) PCT Filed: Oct. 10, 2023
(86) PCT No.: PCT/CN2023/123741

§ 371 Date: Oct. 15, 2024

(30) Foreign Application Priority Data
Nov. 29, 2022 (CN) 202211511404.8

(51) Int. Cl. H10K 59/126; H10K 59/131; H10K 59/80

(52) U.S. Cl. CPC H10K 59/126; H10K 59/131; H10K 59/873

(57) ABSTRACT

A display panel includes a display region, at least one opening region and an opening edge region located between the opening region and the display region. The opening edge region at least partially surrounds the opening region. The opening edge region includes a first isolation region, an encapsulation region and a second isolation region that are sequentially arranged in a direction from the opening region to the display region. The display panel includes a substrate and a light-shielding layer disposed on a side of the substrate. A ratio of an area of an orthographic projection of a portion of the light-shielding layer located in the first isolation region, the encapsulation region and the second isolation region to a sum of areas of the first isolation region, the encapsulation region and the second isolation region is in a range of 30% to 62%, inclusive.

### CROSS-REFERENCE TO RELATED APPLICATIONS

This application is a national phase entry under 35 USC 371 of International Patent Application No. PCT/CN2023/123741, filed on Oct. 10, 2023, which claims priority to Chinese Patent Application No. 202211511404.8, filed on Nov. 29, 2022, each are incorporated herein by reference in their entirety.

### TECHNICAL FIELD

The present disclosure relates to the field of display technologies, and in particular, to a display panel and a display device.

### BACKGROUND

With the rapid development of display technologies, display devices have gradually become common in people's lives. Organic light-emitting diodes (OLEDs) are widely used in smart products such as mobile phones, televisions, and notebook computers due to their advantages of self-luminous, low power consumption, wide viewing angle, fast response speed, high contrast, and flexible display. Active-matrix organic light-emitting diode (AMOLED) is called the next generation display technology.

### SUMMARY

In an aspect, a display panel is provided, and the display panel includes a display region, at least one opening region, and an opening edge region located between the opening region and the display region. The opening edge region at least partially surrounds the opening region. The opening edge region includes a first isolation region, an encapsulation region and a second isolation region that are sequentially arranged in a first direction, and the first direction is a direction from the opening region to the display region. The display panel includes a substrate and a light-shielding layer disposed on a side of the substrate. A ratio of an area of an orthographic projection of a portion of the light-shielding layer located in the first isolation region, the encapsulation region and the second isolation region to a sum of area of the first isolation region, the encapsulation region and the second isolation region is in a range of 30% to 62%, inclusive.

In some embodiments, the first isolation region includes a first light-shielding layer removal region disposed in the first isolation region and proximate to the opening region, and the first light-shielding layer removal region is provided with no light-shielding layer therein.

In some embodiments, a dimension of the first light-shielding layer removal region in the first direction is in a range of 10 μm to 25 μm, inclusive.

In some embodiments, the first isolation region includes a plurality of first isolation pillars arranged at intervals in the first direction, and each first isolation pillar of the plurality of first isolation pillars surrounds the opening region. The first isolation region includes a first light-shielding layer removal region, the first light-shielding layer removal region covers an orthographic projection of a first isolation pillar proximate to the opening region of the plurality of first isolation pillars on the substrate.

In some embodiments, the first isolation region includes a second light-shielding layer removal region disposed in the first isolation region and proximate to the encapsulation region. The second isolation region includes a third light-shielding layer removal region disposed in the second isolation region and proximate to the encapsulation region. The second light-shielding layer removal region, the encapsulation region and the third light-shielding layer removal region are provided with no light-shielding layer therein. The second light-shielding layer removal region, the encapsulation region and the third light-shielding layer removal region are sequentially connected in the first direction.

In some embodiments, a sum of dimensions in the first direction of the second light-shielding layer removal region, the encapsulation region and the third light-shielding layer removal region is greater than or equal to 60 μm. A dimension of the second light-shielding layer removal region in the first direction is in a range of 3 μm to 7 μm, inclusive. A dimension of the third light-shielding layer removal region in the first direction is in a range of 30 μm to 60 μm, inclusive. A dimension of the encapsulation region in the first direction is in a range of 40 μm to 60 μm, inclusive.

In some embodiments, a portion of the light-shielding layer located in the first isolation region, the encapsulation region and the second isolation region is provided with a plurality of first light-transmitting holes therein, and the plurality of first light-transmitting holes are arranged in an array in the first direction and a second direction. The second direction is a direction surrounding the opening region.

In some embodiments, a dimension in the first direction of a region of the light-shielding layer where the plurality of first light-transmitting holes are disposed is in a range of 150 μm to 600 μm, inclusive.

In some embodiments, a dimension of each first light-transmitting hole of the plurality of first light-transmitting holes is in a range of 15 μm to 40 μm, inclusive. A distance, in the first direction, between every two adjacent first light-transmitting holes of the plurality of first light-transmitting holes is in a range of 15 μm to 40 μm, inclusive. A distance, in the second direction, between every two adjacent first light-transmitting holes of the plurality of first light-transmitting holes is in a range of 15 μm to 40 μm, inclusive.

In some embodiments, the opening edge region further includes a light-shielding layer bridge region, and the light-shielding layer bridge region overlaps the encapsulation region, a first portion of the first isolation region proximate to the encapsulation region, and a second portion of the second isolation region proximate to the encapsulation region. A portion of the light-shielding layer located in the light-shielding layer bridge region includes connection bridges and second light-transmitting holes that are alternately arranged in a second direction. The second direction is a direction surrounding the opening region.

In some embodiments, a dimension of the first portion in the first direction is in a range of 3 μm to 7 μm, inclusive; and a dimension of the second portion in the first direction is in a range of 30 μm to 60 μm, inclusive.

In some embodiments, a ratio of a dimension, in the second direction, of a connection bridge of the connection bridges at a shortest position to a sum of dimensions, in the second direction, of the connection bridge at the shortest position and a second light-transmitting hole adjacent to the connection bridge at a shortest position is in a range of 40% to 62%, inclusive.

In some embodiments, the dimension, in the second direction, of the connection bridge at the shortest position is greater than or equal to 30 μm. A dimension, in the second direction, of the second light-transmitting hole at the shortest position is less than or equal to 20 μm.

In some embodiments, a dimension of the light-shielding layer bridge region in the first direction is greater than or equal to 60 μm.

In some embodiments, the encapsulation region is provided with an encapsulation dam therein, and the encapsulation dam surrounds the opening region. The first isolation region includes a plurality of first isolation pillars arranged at intervals in the first direction, and each first isolation pillar of the plurality of first isolation pillars surrounds the opening region. The second isolation region includes a plurality of second isolation pillars arranged at intervals in the first direction, and each second isolation pillar of the plurality of second isolation pillars surrounds the opening region.

In some embodiments, the display panel further includes at least one of a first source-drain metal layer and second source-drain metal layer, a first planarization layer, a second planarization layer and a first support layer that are disposed between the substrate and the light-shielding layer. The at least one of the first source-drain metal layer and second source-drain metal layer, the first planarization layer, the second planarization layer and the first support layer are arranged in sequence in a third direction. The third direction is a direction from the substrate to the light-shielding layer. The first isolation pillars and the second isolation pillars are disposed in a same layer as the at least one of the first source-drain metal layer and second source-drain metal layer. The encapsulation dam includes a third portion, a fourth portion and a fifth portion that are sequentially stacked in the third direction. The third portion is disposed in a same layer as the first planarization layer, the fourth portion is disposed in a same layer as the second planarization layer, and the fifth portion is disposed in a same layer as the first support layer.

In some embodiments, the display panel further includes a first inorganic encapsulation film layer, an organic encapsulation film layer, a second inorganic encapsulation film layer and a third planarization layer that are disposed on a side of the first support layer away from the substrate. The first inorganic encapsulation film layer, the organic encapsulation film layer, the second inorganic encapsulation film layer, the light-shielding layer and the third planarization layer are sequentially stacked in the third direction. The third planarization layer overlaps the first isolation region, the encapsulation region and the second isolation region. In the second isolation region, the first inorganic encapsulation film layer, the organic encapsulation film layer and the second inorganic encapsulation film layer are sequentially arranged between the second isolation pillars and the light-shielding layer.

In some embodiments, the display panel further includes a first gate conductive layer and a second gate conductive layer that are disposed between the substrate and a first source-drain metal layer. The first gate conductive layer and the second gate conductive layer are arranged in the third direction. A first isolation pillar of the plurality of first isolation pillars and a second isolation pillar of the plurality of second isolation pillars are each provided with a first support portion and a second support portion on a side proximate to the substrate. The first support portion is disposed in a same layer as the first gate conductive layer, and the second support portion is disposed in a same layer as the second gate conductive layer.

In some embodiments, the opening edge region further includes a wiring region disposed on a side of the second isolation region proximate to the display region, and a dimension, in the first direction, of a portion of the light-shielding layer in the first isolation region, the encapsulation region, the second isolation region and the wiring region is greater than or equal to 580 μm.

In another aspect, a display device is provided. The display device includes the display panel according to any one of the above embodiments.

### BRIEF DESCRIPTION OF THE DRAWINGS

In order to describe technical solutions in the present disclosure more clearly, the accompanying drawings to be used in some embodiments of the present disclosure will be introduced briefly below. Obviously, the accompanying drawings to be described below are merely drawings of some embodiments of the present disclosure, and a person of ordinary skill in the art can obtain other drawings according to those drawings. In addition, the accompanying drawings in the following description may be regarded as schematic diagrams, but are not limitations on actual sizes of products, actual processes of methods and actual timings of signals involved in the embodiments of the present disclosure.

FIG. 1 is a structural diagram of a display device, in accordance with some embodiments;

FIG. 2 is a structural diagram of a display panel, in accordance with some embodiments of the present disclosure;

FIG. 3 is a sectional view of the display panel in FIG. 2 taken along the section line BB, in accordance with some embodiments of the present disclosure;

FIG. 4 is an enlarged view of the position C of the display panel in FIG. 2, in accordance with some embodiments of the present disclosure;

FIG. 5 is an enlarged view of the position D of the display panel in FIG. 4, in accordance with some embodiments of the present disclosure;

FIG. 6 is another sectional view of the display panel in FIG. 2 taken along the section line BB, in accordance with some embodiments of the present disclosure;

FIG. 7 is another enlarged view of the position C of the display panel in FIG. 2, in accordance with some embodiments of the present disclosure;

FIG. 8 is an enlarged view of the position E of the display panel in FIG. 7, in accordance with some embodiments of the present disclosure;

FIG. 9 is an enlarged view of the position G of the display panel in FIG. 8, in accordance with some embodiments of the present disclosure;

FIG. 10 is yet another enlarged view of the position C of the display panel in FIG. 2, in accordance with some embodiments of the present disclosure;

FIG. 11 is an enlarged view of the position I of the display panel in FIG. 10, in accordance with some embodiments of the present disclosure;

FIG. 12 is a sectional view of the display panel in FIG. 11 taken along the section line JJ, in accordance with some embodiments of the present disclosure;

FIG. 13 is another structural diagram of a display panel, in accordance with some embodiments of the present disclosure;

FIG. 14 is a structural diagram of a module, in accordance with some embodiments of the present disclosure; and

FIG. 15 is a structural diagram of a display device, in accordance with some embodiments of the present disclosure.

### DETAILED DESCRIPTION

The technical solutions in some embodiments of the present disclosure will be described clearly and completely below in conjunction with the accompanying drawings. Obviously, the embodiments to be described are merely some but not all embodiments of the present disclosure. All other embodiments obtained by a person of ordinary skill in the art based on embodiments of the present disclosure should belong to the protection scope of the present disclosure.

Unless the context requires otherwise, throughout the description and claims, the term “comprise” and other forms thereof such as the third-person singular form “comprises” and the present participle form “comprising” are construed as an open and inclusive meaning, i.e., “including, but not limited to”. In the description of the specification, terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, terms such as “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, the term “a/the plurality of” means two or more unless otherwise specified.

In the description of some embodiments, terms such as “coupled” and “connected” and derivatives thereof may be used. The term “connected” should be understood in a broad sense, for example, the term “connected” may represent a fixed connection, or a detachable connection, or a one-piece connection; alternatively, the term “connected” may represent a direct connection, or an indirect connection through an intermediate medium. The term “coupled”, for example, indicates that two or more components are in direct physical or electrical contact. The term “coupled” or “communicatively coupled” may also indicate that two or more components are not in direct contact with each other, but still cooperate or interact with each other. The embodiments disclosed herein are not necessarily limited to the context herein.

The phrase “at least one of A, B and C” has the same meaning as the phrase “at least one of A, B or C”, both including following combinations of A, B and C: only A, only B, only C, a combination of A and B, a combination of A and C, a combination of B and C, and a combination of A, B and C.

The phrase “A and/or B” includes following three combinations: only A, only B, and a combination of A and B.

The term such as “about”, “substantially” or “approximately” as used herein includes a stated value and an average value within an acceptable range of deviation of a particular value. The acceptable range of deviation is determined, for example, by a person of ordinary skill in the art, considering measurement in question and errors (i.e., limitations of a measurement system) associated with measurement of a particular quantity.

The term such as “parallel”, “perpendicular” or “equal” as used herein includes a stated condition and a condition similar to the stated condition, the range of the similar condition is within an acceptable range of deviation, and the acceptable range of deviation is determined by, for example, a person of ordinary skill in the art, considering measurement in question and errors (i.e., limitations of a measurement system) associated with measurement of a particular quantity. For example, the term “parallel” includes absolute parallelism and approximate parallelism, and an acceptable range of deviation of the approximate parallelism may be, for example, a deviation within 5°; the term “perpendicular” includes absolute perpendicularity and approximate perpendicularity, and an acceptable range of deviation of the approximate perpendicularity may also be, for example, a deviation within 5°; and the term “equal” includes absolute equality and approximate equality, and an acceptable range of deviation of the approximate equality may be, for example, that a difference between two equals is less than or equal to 5% of either of the two equals.

It will be understood that, when a layer or element is referred to as being on another layer or substrate, it may be that the layer or element is directly on the another layer or substrate, or it may be that intervening layer(s) exist between the layer or element and the another layer or substrate.

Exemplary embodiments are described herein with reference to sectional views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of the regions in a device, and are not intended to limit the scope of the exemplary embodiments.

With the development of active-matrix organic light-emitting diode (AMOLED) screens, due to the demand for light emission effect, power consumption and thickness reduction of the screen, the color filter on encapsulation (COE, i.e., color filter directly on the encapsulation layer) technology has gradually become a requirement for mainstream terminal devices.

The COE technology is a technology that uses a color filter to replace external polarizers, which saves a lot of production costs and has greater production benefits. In addition, an AMOLED screen adopting the COE technology has a higher light extraction rate and better bending resistance, which can meet the performance requirements of the product.

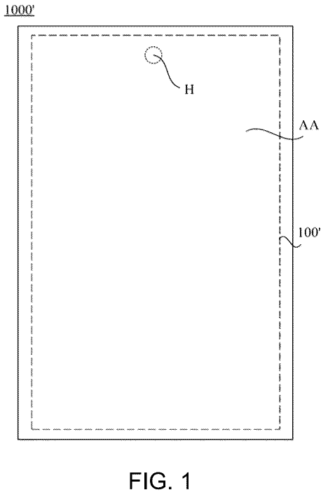

Generally, as shown in FIG. 1, a display device 1000′ includes a display panel 100′ and other electronic components, such as a camera. The display panel 100′ includes a display region AA and at least one opening region H, and the electronic components are disposed in the hole of the opening region H.

However, in the COE technology, due to the lack of shield of the polarizer, a super clean foam (SCF) composite film will shift in position when attached at the opening region H of the screen. Meanwhile, since the region around the opening region H has a relatively high light reflectivity, white edge will occur due to light leakage at the opening region H of the screen, resulting in abnormal display around the opening region H of the screen. If a black matrix (BM) is used to completely block the region around the opening region H of the screen, although the problem of light leakage may be effectively alleviated, it cannot meet the requirement for rainbow mura detection in an even after cutting (EAC, which means that a rigid glass backplate is changed into a more flexible product) process section and a module process section due to completely blocked for the region around the opening region H of the screen.

It will be noted that, the method for detecting rainbow mura in the EAC process section and the module process section is to allow a light source to be illuminated onto a product to detect the rainbow mura by receiving the reflected light. Since the BM layer is opaque, the covering manner of the BM layer will affect the success rate of rainbow mura detection.

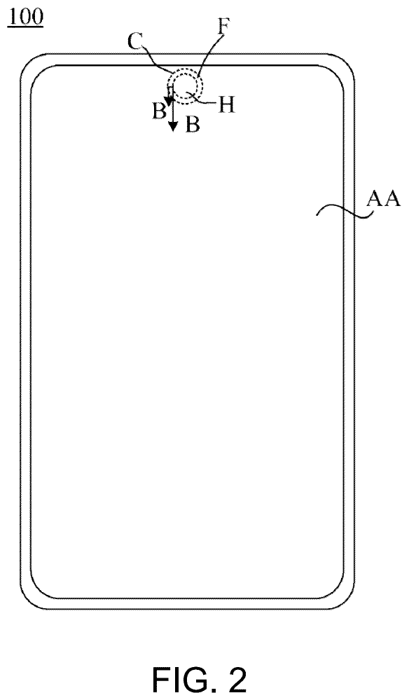

Based on this, as shown in FIG. 2, some embodiments of the present disclosure provide a display panel 100, and the display panel 100 includes a display region AA, at least one opening region H, and an opening edge region F that is located between the opening region H and the display region AA. The opening edge region F at least partially surrounds the opening region H.

In some examples, as shown in FIG. 2, the display panel 100 includes one opening region H, and the opening region H is in a shape of, for example, a circle or substantially is in a shape of a circle, such as an ellipse. A region between the opening region H and the display region AA is the opening edge region F. The opening edge region F surrounds the opening region H, which means that the opening edge region F is arranged around the opening region H, and the display region AA surrounds the opening edge region F and the opening region H. There may exist multiple opening regions H, and each opening region H is surrounded by an opening edge region F. The number of the opening regions H may be set as required and is not limited here.

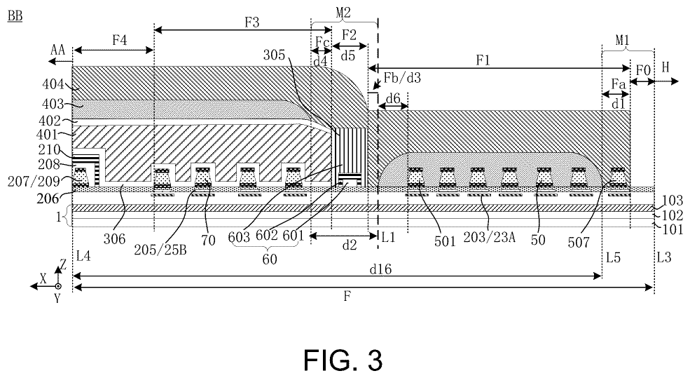

As shown in FIG. 3, the opening edge region F includes a first isolation region F1, an encapsulating region F2, and a second isolation region F3 that are arranged in sequence in a first direction X. The first direction X is a direction from the opening region H to the display region AA. The display panel 100 includes a substrate 1 and a light-shielding layer 403 disposed on a side of the substrate 1.

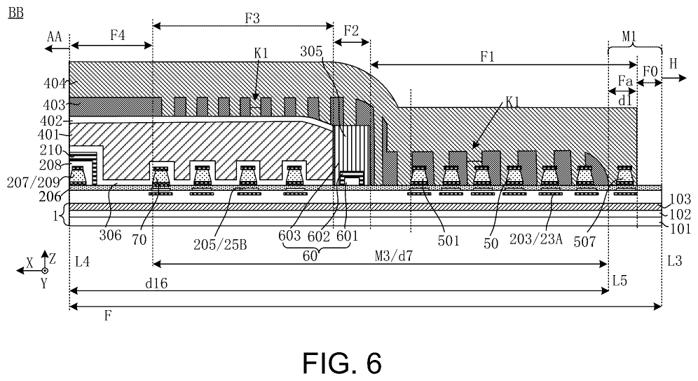

It will be noted that, FIGS. 3 and 6 are sectional views respectively obtained along a section line of display panels 100 with two structures, and the position of the section lines corresponding to FIGS. 3 and 6 in the display panel 100 is the same as the position of the section line BB in the display panel 100 shown in FIG. 2.

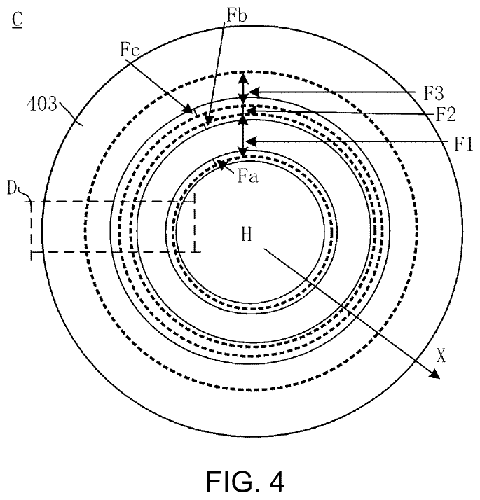

For example, as shown in FIG. 4, the first isolation region F1, the encapsulating region F2, and the second isolation region F3 are each of an annular structure surrounding the opening region H.

It will be noted that, FIGS. 4, 7 and 10 are respectively enlarged views of display panels 100 with three structures at a position, and the position in the display panel 100 in FIGS. 4, 7 and 10 is the same as the position C in the display panel 100 shown in FIG. 2.

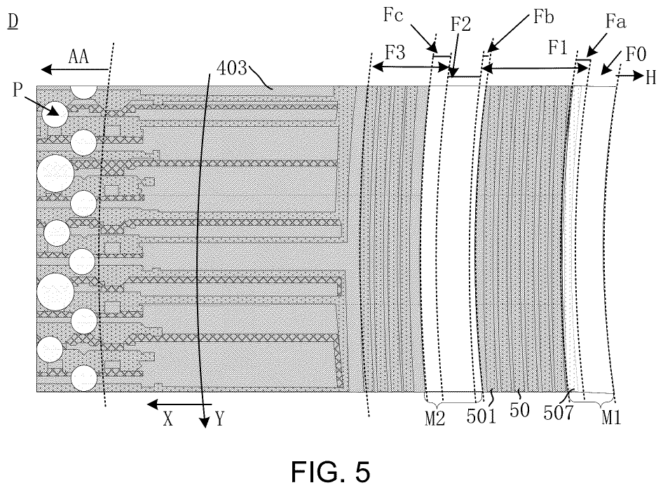

It will be noted that, in order to clearly illustrate the design of the shielding layer 403 in the opening edge region F, in FIG. 4 and the following FIGS. 5, 7, 8, 9, 10 and 11, it mainly illustrates the structure of the shielding layer 403, and the design of other film layers may refer to the sectional views shown in FIGS. 3, 6 and 12.

It will be understood that, the substrate 1 has an opening in the opening region H. An electronic device may be provided in the opening of the display panel 100. For example, an optical sensor may be provided. Therefore, the opening of the opening region H may penetrate the substrate 1, so that light transmittance is relatively high.

For example, the substrate 1 may be of a single-layer structure or a multi-layer structure. For example, as shown in FIG. 3, the substrate 1 may include a glass layer 101, a flexible base layer 102 and a waterproof layer 103 that are sequentially stacked. A material of the flexible base layer 102 includes polyimide, and a material of the waterproof layer 103 may include silicon nitride.

For example, the light-shielding layer 403 includes a black matrix (BM).

For example, as shown in FIGS. 3, 6 and 12, the opening edge region F further includes a cutting-line region F0 disposed on a side of the first isolation region F1 proximate to the opening region H. Cutting is performed at a border line L3 of the cutting line region F0 proximate to the opening region H to form an opening region H for placing an electronic device. For example, a dimension of the cutting line region F0 in the first direction X is in a range of 10 μm to 20 μm, inclusive.

As shown in FIGS. 3, 6 and 12, a ratio of an area of an orthographic projection of a portion of the light-shielding layer 403 located in the first isolation region F1, the encapsulation region F2 and the second isolation region F3 on the substrate 1 to a sum of areas of the first isolation region F1, the encapsulation region F2 and the second isolation region F3 is in a range of 30% to 62%, inclusive.

For example, as shown in FIG. 3, the ratio of the area of the orthographic projection of the portion of the light-shielding layer 403 located in the first isolation region F1, the encapsulation region F2, and the second isolation region F3 on the substrate 1 to the sum of areas of the first isolation region F1, the encapsulation region F2, and the second isolation region F3 is 30%, 40%, 50%, 55%, 60%, 62%, or the like, which is not limited here.

It will be noted that, the first isolation region F1, the encapsulation region F2, and the second isolation region F3 have different film layer structures, which will be described in detail in the subsequent contents and will not be described in detail here.

That is, the light-shielding layer 403 is disposed in the first isolation region F1, the encapsulation region F2, and the second isolation region F3, but the light-shielding layer 403 does not completely cover the first isolation region F1, the encapsulation region F2, and the second isolation region F3.

With the design in which the light-shielding layer 403 is disposed around the opening region H, i.e., in the opening edge region F, the light-shielding layer 403 does not completely cover the first isolation region F1, the encapsulation region F2 and the second isolation region F3, and the ratio of the area of the orthographic projection of the portion of the light-shielding layer 403 located in the first isolation region F1, the encapsulation region F2, and the second isolation region F3 on the substrate 1 to the sum of areas of the first isolation region F1, the encapsulation region F2 and the second isolation region F3 is in the range of 30% to 62%, inclusive, light reflection in the opening edge region F may be effectively reduced, and the problem of white edge caused by light leakage may be effectively alleviated. Moreover, the region where the light-shielding layer 403 is not provided may meet the requirement for rainbow mura detection.

In some embodiments, as shown in FIGS. 3, 6 and 12, the first isolation region F1 includes a first light-shielding layer removal region Fa. The first light-shielding layer removal region Fa is disposed in the first isolation region F1 and proximate to the opening region H, and the first light-shielding layer removal region Fa is provided with no light-shielding layer 403 therein.

For example, as shown in FIG. 4, the first light-shielding layer removal region Fa is of an annular structure arranged around the opening region H.

For example, the light-shielding layer 403 in a region of the first isolation region F1 proximate to the opening region H is removed, i.e., the light-shielding layer 403 is not provided in this region, so that the first light-shielding layer removal region Fa is formed. The first light-shielding layer removal region Fa is not covered by the light-shielding layer 403. For example, as shown in FIG. 5, there is no light-shielding layer 403 on a side of the first light-shielding layer removal region Fa proximate to the opening region H; that is, the cutting-line region F0 is not provided with the light-shielding layer 403 therein. The first light-shielding layer removal region Fa and the cutting-line region F0 are referred to as a first region M1, and the first region M1 is not provided with the light-shielding layer 403 therein. Therefore, the first region M1 may be used for rainbow mura detection.

In some embodiments, as shown in FIG. 3, a dimension d1 of the first light-shielding layer removal region Fa in the first direction X is in a range of 10 μm to 25 μm, inclusive.

For example, as shown in FIG. 3, the dimension d1 of the first light-shielding layer removal region Fa in the first direction X is 10 μm, 13 μm, 15 μm, 18 μm, 20 μm, 23 μm or 25 μm, which is not limited here.

That is, a dimension of the first light-shielding layer removal region Fa in a radial direction of the opening region H is in a range of 10 μm to 25 μm, inclusive.

With the design that the first light-shielding layer removal region Fa with a dimension d1 in a range of 10 μm to 25 μm in the first direction X is disposed in the first isolation region F1 and proximate to the opening region H, it is possible to provide conditions for rainbow mura detection while avoiding the problem of white edge caused by light leakage in the opening edge region F.

In some embodiments, as shown in FIGS. 3, 6 and 12, the first isolation region F1 includes a plurality of first isolation pillars 50 arranged at intervals in the first direction X. Each first isolation pillar 50 of the plurality of first isolation pillars 50 surrounds the opening region H. The first isolation region F1 includes the first light-shielding layer removal region Fa, and the first light-shielding layer removal region Fa covers an orthographic projection of a first isolation pillar 50 proximate to the opening region H in the plurality of first isolation pillars 50 on the substrate 1.

For example, as shown in FIGS. 3 and 5, the plurality of first isolation pillars 50 are arranged at intervals in the radial direction of the opening region H; that is, the plurality of first isolation pillars 50 are all of an annular structure surrounding the opening region H, and the diameters of the plurality of first isolation pillars 50 increase successively along the first direction X. The plurality of first isolation pillars 50 are disposed in the first isolation region F1, which may improve the encapsulation capability for the opening edge region F and help to isolate the corrosion of water vapor.

For example, as shown in FIGS. 3 and 5, seven first isolation pillars 50 are disposed in the first isolation region F1 in the first direction X, and a first isolation pillar 50 proximate to the opening region H is a seventh first isolation pillar 507. That is, the first light-shielding layer removal region Fa covers an orthographic projection of the seventh first isolation pillar 50 on the substrate 1.

In other words, the light-shielding layer 403 is not disposed on a side of the seventh first isolation pillar 507 away from the substrate 1.

In some embodiments, as shown in FIGS. 3 to 5, the first isolation region F1 includes a second light-shielding layer removal region Fb, and the second light-shielding layer removal region Fb is disposed in the first isolation region F1 and proximate to the encapsulation region F2. The second isolation region F3 includes a third light-shielding layer removal region Fc, and the third light-shielding layer removal region Fc is disposed in the second isolation region F3 and proximate to the encapsulation region F2. The second light-shielding layer removal region Fb, the encapsulation region F2 and the third light-shielding layer removal region Fc are provided with no light-shielding layer 403 therein. The second light-shielding layer removal region Fb, the encapsulation region F2 and the third light-shielding layer removal region Fc are sequentially connected in the first direction X.

For example, as shown in FIG. 4, the second light-shielding layer removal region Fb and the third light-shielding layer removal region Fc are both of an annular structure arranged around the opening region H.

For example, as shown in FIGS. 3 to 5, the light-shielding layer 403 in a region in the first isolation region F1 proximate to the encapsulation region F2 is removed, i.e., the light-shielding layer 403 is not disposed in this region, so that the second light-shielding layer removal region Fb is formed. The second light-shielding layer removal region Fb is not covered by the light-shielding layer 403 and may be used for rainbow mura detection.

The light-shielding layer 403 in a region in the second isolation region F3 proximate to the encapsulation region F2 is removed, i.e., the light-shielding layer 403 is not disposed in this region, so that the third light-shielding layer removal region Fc is formed. The third light-shielding layer removal region Fc is not covered by the light-shielding layer 403 and may be used for rainbow mura detection. The light-shielding layer 403 is not disposed in the encapsulation region F2, i.e., the encapsulation region F2 is not covered by the light-shielding layer 403, and may be used for the rainbow mura detection.

For example, as shown in FIG. 5, the second light-shielding layer removal region Fb, the encapsulation region F2 and the third light-shielding layer removal region Fc are sequentially connected in the first direction X. That is, the second light-shielding layer removal region Fb is disposed on a side of the encapsulation region F2 in the first direction X, and the third light-shielding layer removal region Fc is disposed on the other side of the encapsulation region F2 in the first direction X. The second light-shielding layer removal region Fb, the encapsulation region F2 and the third light-shielding layer removal region Fc form a second region M2 as a whole that is not covered by the light-shielding layer 403. The second region M2 may be used for rainbow mura detection.

In some embodiments, as shown in FIG. 3, a sum of dimensions (the sum of dimensions is donated as d2) of the second light-shielding layer removal region Fb, the encapsulation region F2 and the third light-shielding layer removal region Fc in the first direction X is greater than or equal to 60 μm, i.e., d2≥60 μm.

For example, the sum d2 of dimensions of the second light-shielding layer removal region Fb, the encapsulation region F2 and the third light-shielding layer removal region Fc in the first direction X is 60 μm, 62 μm, 65 μm, 68 μm or 70 μm, which is not limited here. That is, a dimension of the second region M2 in the first direction X for detecting rainbow mura is greater than or equal to 60 μm.

In a case where the sum d2 of dimensions of the second light-shielding layer removal region Fb, the encapsulation region F2 and the third light-shielding layer removal region Fc in the first direction X is greater than or equal to 60 μm, it may be ensured that this region meets the requirement for rainbow mura detection.

In some embodiments, as shown in FIG. 3, a dimension d3 of the second light-shielding layer removal region Fb in the first direction X is in a range of 3 μm to 7 μm, inclusive, i.e., 7 μm≥d3≥3 μm. A dimension d4 of the third light-shielding layer removal region Fc in the first direction X is in a range of 30 μm to 60 μm, inclusive, i.e., 60 μm≥d4≥30 μm. A dimension d5 of the encapsulation region F2 in the first direction X is in a range of 40 μm to 60 μm, inclusive; that is, 60 μm≥d5≥40 μm.

For example, a dimension d3 of the second light-shielding layer removal region Fb in the first direction X is 3 μm, 4 μm, 5 μm, 6 μm or 7 μm, which is not limited here.

By setting the dimension of the second light-shielding layer removal region Fb in the first direction X to be in the range of 3 μm to 7 μm, inclusive, it may be ensured that the dimension of the second region M2 in the first direction X meets the requirement for rainbow mura detection.

As shown in FIG. 3, a first isolation pillar 50 in the first isolation region F1 proximate to the encapsulation region F2 is referred to as a first first isolation pillar 501, and a distance d6 between a border line L1 of the second light-shielding layer removal region Fb proximate to the first first isolation pillar 501 and the first first isolation pillar 501 in the first direction X is greater than or equal to 6 μm, i.e., d6≥6 μm. With such an arrangement, it may be possible to prevent the light-shielding layer 403 in the first isolation region F1 from falling off. That is, by setting the dimension of the second light-shielding layer removal region Fb in the first direction X to be in a range of 3 μm to 7 μm, inclusive, it is ensured that the distance d6 between the border line L1 of the second light-shielding layer removal region Fb proximate to the first first isolation pillar 501 and the first first isolation pillar 501 in the first direction X is greater than or equal to 6 μm while ensuring that the requirement for rainbow mura detection is met, so as to prevent the problem of falling off of the light-shielding layer 403 in the first isolation region F1.

For example, the dimension d4 of the third light-shielding layer removal region Fc in the first direction X is 30 μm, 35 μm, 40 μm, 45 μm, 50 μm or 60 μm, which is not limited here.

By setting the dimension d4 of the third light-shielding layer removal region Fc in the first direction X to be in the range of 30 μm to 60 μm, inclusive, the problem of falling off of the light-shielding layer 403 in the second isolation region F3 may be avoided while ensuring that the requirement for rainbow mura detection is met.

For example, the dimension d5 of the encapsulation region F2 in the first direction X is 40 μm, 45 μm, 50 μm, 55 μm or 60 μm, which is not limited here.

With such an arrangement in which the dimension d5 of the encapsulation region F2 in the first direction X to be in the range of 40 μm to 60 μm, inclusive, the third light-shielding layer removal region Fc and the second light-shielding layer removal region Fb are respectively disposed on two sides of the encapsulation region F2 in the first direction X, the dimension d3 of the second light-shielding layer removal region Fb in the first direction X is in the range of 3 μm to 7 μm, inclusive, and the dimension d4 of the third light-shielding layer removal region Fc in the first direction X is in the range of 30 μm to 60 μm, inclusive, it is effectively ensured that the dimension d2, in the first direction X, of the second region M2 in which the light-shielding layer 403 is not provided is greater than or equal to 60 μm, so that the design of the light-shielding layer 403 in the opening edge region F meets the requirement for rainbow mura detection.

In some embodiments, as shown in FIG. 6, the portion of the light-shielding layer 403 located in the first isolation region F1, the encapsulation region F2, and the second isolation region F3 is provided with a plurality of first light-transmitting holes K1 therein, and the plurality of first light-transmitting holes K1 are arranged in an array in the first direction X and the second direction Y. The second direction Y is a direction surrounding the opening region H.

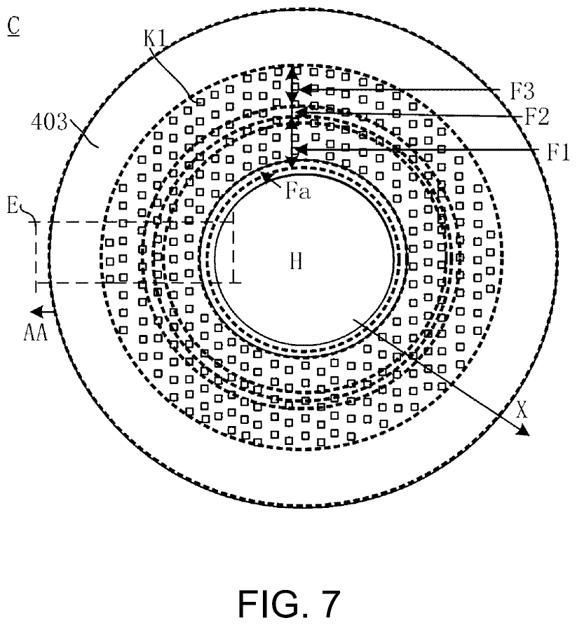

For example, as shown in FIGS. 6 and 7, the first light-transmitting holes K1 are light-transmitting regions formed by removing portions of the light-shielding layer 403 from the entire light-shielding layer 403. For example, the portions of the light-shielding layer 403 are removed in a manner of an array arrangement from the entire light-shielding layer 403 to form the light-shielding layer 403 having the first light-transmitting holes K1 arranged in an array.

For example, as shown in FIG. 6, the first direction X is perpendicular to the second direction Y.

With the design in which the plurality of first light-transmitting holes K1 are arranged in an array in the light-shielding layer 403 in the first isolation region F1, the encapsulation region F2 and the second isolation region F3, the design of the light-shielding layer 403 in the opening edge region F meets the requirement for rainbow mura detection.

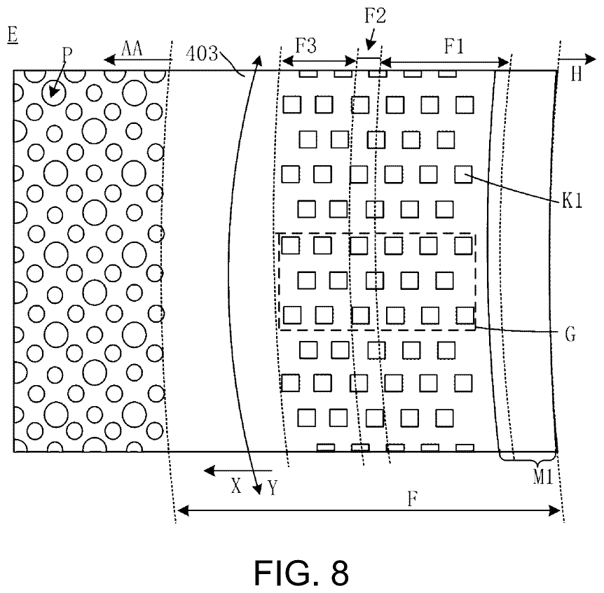

For example, as shown in FIG. 8, a ratio of an area of an orthographic projection, on the substrate 1, of the portion of the light-shielding layer 403 that is provided with the plurality of first light-transmitting holes K1 and located in the first isolation region F1, the encapsulation region F2 and the second isolation region F3 to the sum of the areas of the first isolation region F1, the encapsulation region F2 and the second isolation region F3 is in the range of 30% to 62%, inclusive.

In some embodiments, as shown in FIG. 6, a dimension d7, in the first direction X, of a region of the light-shielding layer 403 where the plurality of first light-transmitting holes K1 are disposed is in a range of 150 μm to 600 μm, inclusive.

That is, as shown in FIG. 6, the first light-transmitting holes K1 are disposed in the first isolation region F1, the encapsulation region F2 and the second isolation region F3, which means that the first light-transmitting holes K1 are not disposed in the whole region consist of the first isolation region F1, the encapsulation region F2 and the second isolation region F3 that are sequentially connected. For example, a first light-shielding layer removal region Fa is disposed in the first isolation region F1, and the plurality of first light-transmitting holes K1 are disposed in the light-shielding layer 403 in a region that is consist of the first isolation region F1, the encapsulation region F2 and the second isolation region F3 and excluding the first light-shielding layer removal region Fa. This region is denoted as a third region M3.

For example, the dimension d7, in the first direction X, of the region of the light-shielding layer 403 where the plurality of first light-transmitting holes K1 are disposed is 150 μm, 180 μm, 220 μm, 270 μm, 350 μm, 420 μm, 500 μm or 600 μm, which is not limited here.

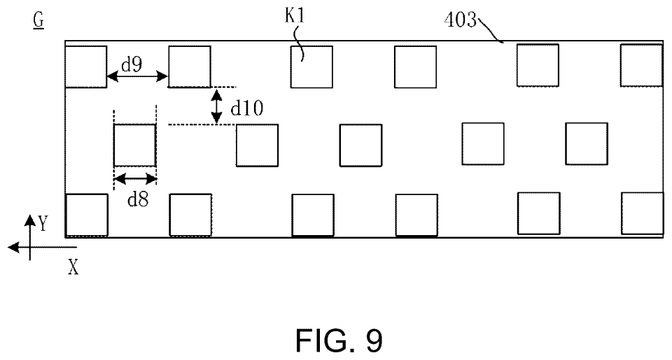

In some embodiments, as shown in FIG. 9, a dimension d8 of each first light-transmitting hole K1 of the plurality of first light-transmitting holes K1 is in a range of 15 μm to 40 μm, inclusive, i.e., 40 μm≥d8≥15 μm. A distance d9, in the first direction X, between every two adjacent first light-transmitting holes K1 of the plurality of first light-transmitting holes K1 is in a range of 15 μm to 40 μm, inclusive, i.e., 40 μm≥d9≥15 μm. A distance d10, in the second direction Y, between every two adjacent first light-transmitting holes K1 of the plurality of first light-transmitting holes K1 is in a range of 15 μm to 40 μm, inclusive, i.e., 40 μm≥d10≥15 μm.

For example, a shape of the first light-transmitting hole K1 includes any one of a square shape and a circular shape. For example, the shape of the first light-transmitting hole K1 in an axial direction of the first light-transmitting hole K1 is a square shape, and the dimension d8 of a side length of the first light-transmitting hole K1 is in the range of 15 μm to 40 μm, inclusive. Alternatively, the shape of the first light-transmitting hole K1 in the axial direction of the first light-transmitting hole K1 is a circular shape, and the dimension d8 of a diameter of the first light-transmitting hole K1 is in the range of 15 μm to 40 μm, inclusive. The shape of the first light-transmitting hole K1 includes any one of a square shape and a circular shape, which is only an example of the shape of the first light-transmitting hole K1, and is not a limitation on the shape of the first light-transmitting hole K1. The first light-transmitting hole K1 may also be in other shapes.

For example, the dimension d8 of the first light-transmitting hole K1 is 15 μm, 20 μm, 25 μm, 30 μm, 35 μm or 40 μm, which is not limited here.

For example, the distance d9, in the first direction X, between two adjacent first light-transmitting holes K1 is 15 μm, 20 μm, 25 μm, 30 μm, 35 μm or 40 μm, which is not limited here.

For example, the distance d10, in the second direction Y, between two adjacent first light-transmitting holes K1 is 15 μm, 20 μm, 25 μm, 30 μm, 35 μm or 40 μm, which is not limited here.

With such a design of the dimension d8 of the first light-transmitting hole K1, the distance d9 between two adjacent first light-transmitting holes K1 in the first direction X and the distance d10 between two adjacent first light-transmitting holes K1 in the second direction Y, the design of the light-shielding layer 403 in the opening edge region F meets the requirement for rainbow mura detection.

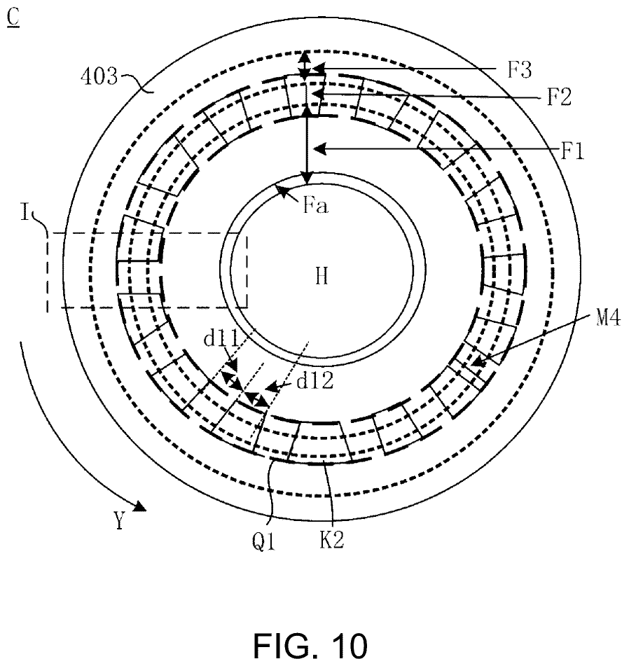

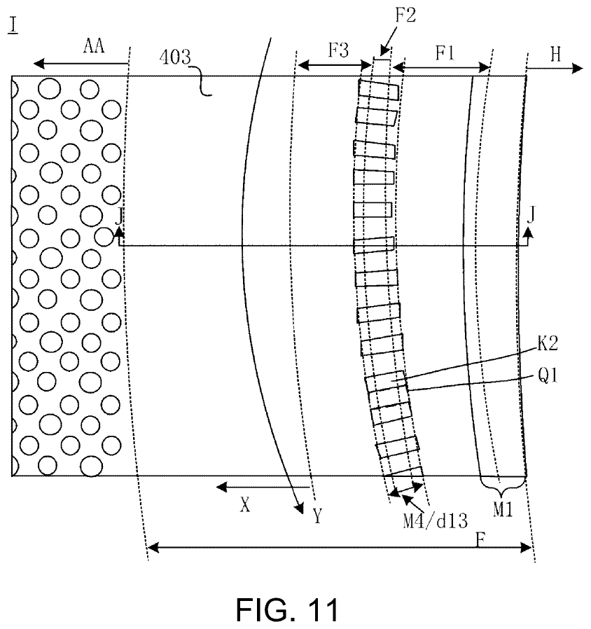

In some embodiments, as shown in FIGS. 10 and 11, the opening edge region F includes a light-shielding layer bridge region M4. A portion of the light-shielding layer 403 located in the light-shielding layer bridge region M4 includes connection bridges Q1 and second light-transmitting holes K2 that are alternately arranged in the second direction Y. The second direction Y is a direction surrounding the opening region H.

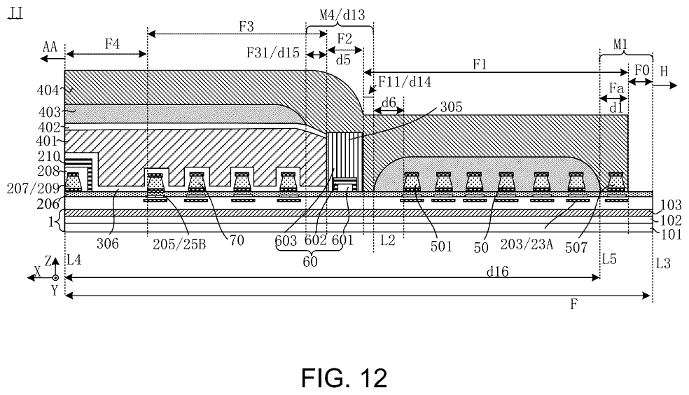

As shown in FIG. 12, the light-shielding layer bridge region M4 overlaps the encapsulation region F2, a first portion F11 of the first isolation region F1 proximate to the encapsulation region F2, and a second portion F31 of the second isolation region F3 proximate to the encapsulation region F2.

For example, as shown in FIG. 10, the second light-transmitting holes K2 are light-transmitting regions formed by removing portions of the light-shielding layer 403.

For example, as shown in FIG. 11, the connection bridges Q1 and the second light-transmitting holes K2 are alternately arranged to form an annular light-shielding layer bridge region M4, and the light-shielding layer bridge region M4 is arranged around the opening region H. The connection bridges Q1 of the light-shielding layer bridge region M4 connect the light-shielding layer 403 in the first isolation region F1 and the light-shielding layer 403 in the second isolation region F3.

It will be noted that, the connection bridges Q1 and the second light-transmitting holes K2 in FIG. 10 are not illustrated with similar size as the connection bridges Q1 and the second light-transmitting holes K2 in FIG. 11, respectively. For example, the connection bridges Q1 and the second light-transmitting holes K2 in FIG. 10 are obviously greater than the connection bridges Q1 and the second light-transmitting holes K2 in FIG. 11 in size, respectively. Such an illustration is not a limitation on the sizes of the connection bridges Q1 and the second light-transmitting holes K2, but is only for illustrating the positional relationship of various structures more clearly.

By providing the light-shielding layer bridge region M4 between the first isolation region F1 and the second isolation region F3 and providing the second light-transmitting holes K2 in the light-shielding layer bridge region M4, the design of the light-shielding layer 403 in the opening edge region F meets the requirement for rainbow mura detection.

For example, as shown in FIG. 10, a ratio of an area of an orthographic projection of a portion of the light-shielding layer 403 that is provided with the plurality of second light-transmitting holes K2 and located in the first isolation region F1, the encapsulation region F2 and the second isolation region F3 on the substrate 1 to the sum of the areas of the first isolation region F1, the encapsulation region F2 and the second isolation region F3 is in a range of 30% to 62%, inclusive.

For example, as shown in FIG. 12, the light-shielding layer bridge region M4 includes three portions that are connected in sequence, which are a first portion F11, the encapsulation region F2 and a second portion F31; that is, the light-shielding layer bridge region M4 is disposed in the encapsulation region F2 and disposed on two sides of the encapsulation region F2 in the first direction X.

In some embodiments, as shown in FIG. 12, a dimension d14 of the first portion F11 in the first direction X is in a range of 3 μm to 7 μm, inclusive. A dimension d15 of the second portion F31 in the first direction X is in a range of 30 μm to 60 μm, inclusive.

For example, the dimension d14 of the first portion F11 in the first direction X is 3 μm, 4 μm, 5 μm, 6 μm or 7 μm, which is not limited here.

For example, as shown in FIG. 12, with the design that the dimension d14 of the first portion F11 in the first direction X is in the range of 3 μm to 7 μm, inclusive, it is ensured that a distance d6, in the first direction X, between a border line L2 of the first portion F11 proximate to the first first isolation pillar 501 and the first first isolation pillar is greater than or equal to 6 μm, i.e., d6≥6 μm, which may effectively prevent the light-shielding layer 403 in the first isolation region F1 from falling off.

For example, as shown in FIG. 12, the dimension d15 of the second portion F31 in the first direction X is 30 μm, 35 μm, 40 μm, 45 μm, 50 μm or 60 μm, which is not limited here.

With the design that the dimension d14 of the first portion F11 in the first direction X is in the range of 3 μm to 7 μm, inclusive, and the dimension d15 of the second portion F31 in the first direction X is in the range of 30 μm to 60 μm, inclusive, the problem of falling off of the light-shielding layer 403 may be avoided while the requirement for rainbow mura detection is met.

In some embodiments, as shown in FIG. 10, a ratio of a dimension d11, in the second direction Y, of a connection bridge Q1 at a shortest position to a sum of dimensions, in the second direction, of the connection bridge Q1 at the shortest position and a second light-transmitting hole K2 adjacent to the connection bridge Q1 at a shortest position (the dimension, in the second direction Y, of the second light-transmitting hole K2 at the shortest position is donated as d12) is in a range of 40% to 62%, inclusive.

That is, the ratio of the dimension d11, in the second direction Y, of the connection bridge Q1 at the shortest position to the sum of the dimension d11, in the second direction Y, of the connection bridge Q1 at the shortest position and a dimension d12, in the second direction Y, of the second light-transmitting hole K2 adjacent to the connection bridge Q1 at the shortest position is in the range of 40% to 62%, inclusive, i.e., 62%≥d11/(d11+d12)≥40%.

For example, as shown in FIG. 10, the ratio of the dimension d11, in the second direction Y, of the connection bridge Q1 at the shortest position to the sum of the dimensions, in the second direction Y, of the connection bridge Q1 and a second light-transmitting hole K2 adjacent to the connection bridge Q1 at the shortest positions, i.e., the ratio of d11/(d11+d12), is 40%, 45%, 50%, 55% or 60%, which is not limited here.

It will be noted that, for example, as shown in FIG. 10, since the light-shielding layer bridge region M4 is of an annular structure, the second light-transmitting holes K2 may be configured to be in a shape of a fan; a dimension, in the second direction Y, of a second light-transmitting hole K2 proximate to the opening region H is less than a dimension, in the second direction Y, of the second light-transmitting hole K2 away from the opening region H; and the dimension, in the second direction Y, of the second light-transmitting hole K2 proximate to the opening region H is the dimension, in the second direction Y, of the second light-transmitting hole K2 at the shortest position. Dimensions of a connection bridge Q1 in the second direction Y may be equal.

For example, the connection bridges Q1 may be configured to be in a shape of a fan or other shapes, which is not limited here.

With the design that the ratio of the dimension d11, in the second direction Y, of the connection bridge Q1 at the shortest position to the sum of the dimensions, in the second direction Y, of the connection bridge Q1 and a second light-transmitting hole K2 adjacent to the connection bridge Q1 at the shortest positions is in the range of 40% to 62%, inclusive, not only the design of the light-shielding layer 403 in the opening edge region F meets the requirement for rainbow mura detection, but also the light-shielding layer 403 is effectively prevented from falling off.

In some embodiments, as shown in FIG. 10, the dimension d11, in the second direction Y, of the connection bridge Q1 at the shortest position is greater than or equal to 30 μm, i.e., d11≥30 μm, and the dimension d12, in the second direction Y, of the second light-transmitting hole K2 at the shortest position is less than or equal to 20 μm, i.e., d12≤20 μm.

For example, in a case where the ratio of the dimension d11, in the second direction Y, of the connection bridge Q1 at the shortest position to the sum of the dimensions, in the second direction Y, of the connection bridge Q1 and a second light-transmitting hole K2 adjacent to the connection bridge Q1 at the shortest positions is in the range of 40% to 62%, inclusive, the dimension d11, in the second direction Y, of the connection bridge Q1 at the shortest position is 30 μm, 35 μm or 40 μm, which is not limited here. The dimension d12, in the second direction Y, of the second light-transmitting hole K2 at the shortest position is 20 μm, 15 μm or 10 μm, which is not limited here.

In some embodiments, as shown in FIGS. 11 and 12, a dimension d13 of the light-shielding layer bridge region M4 in the first direction X is greater than or equal to 60 μm, i.e., d13≥60 μm.

For example, the dimension d13 of the light-shielding layer bridge region M4 in the first direction X is 60 μm, 70 μm, or 80 μm, which is not limited here.

For example, as shown in FIGS. 11 and 12, for the light-shielding layer 403, the second light-transmitting holes K2 disposed in the light-shielding layer bridge region M4 and the first light-shielding layer removal region Fa are both regions for rainbow mura detection. Thus, the requirement that in the first isolation region F1, the encapsulation region F2 and the second isolation region F3, the ratio of the area of the orthographic projection of the light-shielding layer 403 on the substrate 1 to the sum of the areas of the first isolation region F1, the encapsulation region F2 and the second isolation region F3 is in the range of 30% to 62% is met.

In some embodiments, as shown in FIGS. 3, 6 and 12, the encapsulation region F2 is provided with an encapsulation dam 60 therein, and the encapsulation dam 60 surrounds the opening region H. The first isolation region F1 includes a plurality of first isolation pillars 50 arranged at intervals in the first direction X, and each first isolation pillar 50 of the plurality of first isolation pillars 50 surrounds the opening region H. The second isolation region F3 includes a plurality of second isolation pillars 70 arranged at intervals in the first direction X, and each second isolation pillar 70 of the plurality of second isolation pillars 70 surrounds the opening region H.

For example, as shown in FIGS. 3, 6 and 12, the encapsulation dam 60 and the second isolation pillars 70 are both of an annular structure surrounding the opening region H. In the first direction X, the diameters of the plurality of second isolation pillars 70 increase successively. Due to the provision of the encapsulation dam 60, the first isolation pillars 50 and the second isolation pillars 70, it may be possible to improve the encapsulation capability for the opening edge region F to help isolate the corrosion of water vapor.

In some embodiments, as shown in FIGS. 3, 6 and 12, the display panel 100 further includes: at least one of a first source-drain metal layer 207 and second source-drain metal layer 209, a first planarization layer 208, a second planarization layer 210 and a first support layer 305 that are disposed between the substrate 1 and the light-shielding layer 403. The at least one of the first source-drain metal layer 207 and second source-drain metal layer 209, the first planarization layer 208, the second planarization layer 210 and the first support layer 305 are arranged in sequence in a third direction Z. The third direction Z is a direction from the substrate 1 to the light-shielding layer 403. The first isolation pillars 50 and the second isolation pillars 70 are disposed in the same layer as at least one of the first source-drain metal layer 207 and the second source-drain metal layer 209. The encapsulation dam 60 includes a third portion 601, a fourth portion 602 and a fifth portion 603 that are sequentially stacked in the third direction Z. The third portion 601 is disposed in the same layer as the first planarization layer 208, the fourth portion 602 is disposed in the same layer as the second planarization layer 210, and the fifth portion 603 is disposed in the same layer as the first support layer 305.

For example, the materials of the first source-drain metal layer 207 and the second source-drain metal layer 209 include titanium/aluminum/titanium (Ti-AI-Ti). For example, the material of the first source-drain metal layer 207 is titanium/aluminum/titanium (Ti-AI-Ti) stacked in the third direction Z, and the material of the second source-drain metal layer 209 is titanium/aluminum/titanium (Ti-AI-Ti) stacked in the third direction Z. The materials of the first planarization layer 208, the second planarization layer 210 and the first support layer 305 include polyimide.

In some embodiments, as shown in FIGS. 3, 6 and 12, the display panel 100 further includes a first inorganic encapsulation film layer 306, an organic encapsulation film layer 401, a second inorganic encapsulation film layer 402 and a third planarization layer 404 that are disposed on a side of the first support layer 305 away from the substrate 1. The first inorganic encapsulation film layer 306, the organic encapsulation film layer 401, the second inorganic encapsulation film layer 402, the light-shielding layer 403 and the third planarization layer 404 are stacked in sequence in the third direction Z. The third planarization layer 404 overlaps the first isolation region F1, the encapsulation region F2 and the second isolation region F3. In the second isolation region F3, the first inorganic encapsulation film layer 306, the organic encapsulation film layer 401 and the second inorganic encapsulation film layer 402 are sequentially arranged between the second isolation pillars 70 and the light-shielding layer 403.

For example, the first inorganic encapsulation film layer 306 and the second inorganic encapsulation film layer 402 are formed by using a chemical vapor deposition (CVD) process and are used to encapsulate the opening edge region F to isolate water vapor.

With the provision of different film layer structures in the first isolation region F1, the encapsulation region F2 and the second isolation region F3, a relatively good encapsulation effect is achieved in the opening edge region F.

In some embodiments, as shown in FIGS. 3, 6 and 12, the display panel 100 further includes a first gate conductive layer 203 and a second gate conductive layer 205 that are disposed between the substrate 1 and the first source-drain metal layer 207, and the first gate conductive layer 203 and the second gate conductive layer 205 are arranged in the third direction Z. The first isolation pillar 50 and the second isolation pillar 70 are each provided with a first support portion 23A and a second support portion 25B on a side proximate to the substrate 1. The first support portion 23A is disposed in the same layer as the first gate conductive layer 203, and the second support portion 25B is disposed in the same layer as the second gate conductive layer 205.

For example, as shown in FIGS. 3, 6 and 12, the first support portion 23A and the second support portion 25B are both of an annular structure surrounding the opening region H. Orthographic projections of the first isolation pillar 50, the first support portion 23A and the second support portion 25B on the substrate 1 have a common overlapping region. Orthographic projections of the second isolation pillar 70, the first support portion 23A and the second support portion 25B on the substrate 1 have a common overlapping region.

Due to the provision of the first support portion 23A and the second support portion 25B, it is possible to elevate the first isolation pillar 50 and the second isolation pillar 70, thereby improving the encapsulation effect of the first isolation pillars 50 and the second isolation pillars 70 on the opening edge region F.

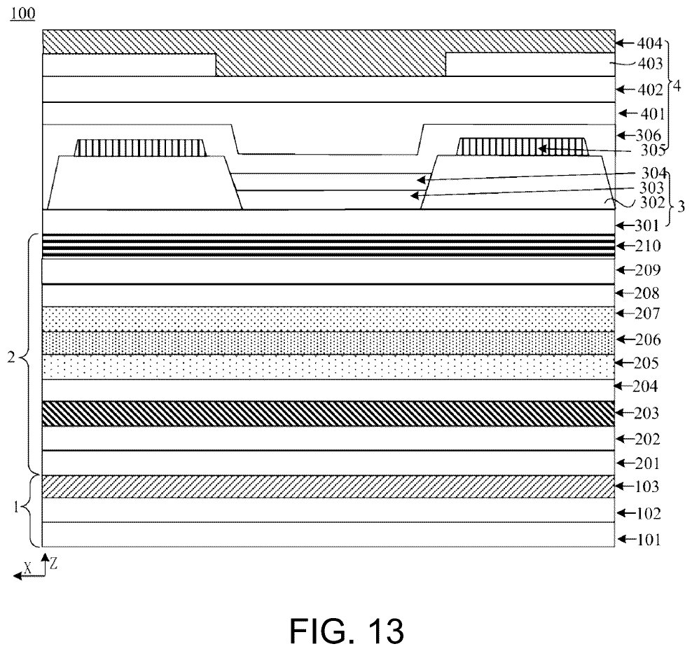

In order to help understanding of the film layer stacking structure of the display panel 100, as shown in FIG. 13, a film layer stacking structure diagram of the display panel 100 is illustrated as an example. It will be understood that, this example is only an example of the film layer stacking structure of the display panel 100, and is not a limitation to the film layer stacking structure of the display panel 100.

As shown in FIG. 13, the display panel 100 includes a substrate 1, and a driving circuit layer 2, a light-emitting device layer 3 and an encapsulation layer 4 that are sequentially stacked on the substrate 1. The driving circuit layer 2 includes a first semiconductor layer 201, a first gate insulating layer 202, a first gate conductive layer 203, a second gate insulating layer 204, a second gate conductive layer 205, an interlayer dielectric layer 206, a first source-drain metal layer 207, a first planarization layer 208, a second source-drain metal layer 209 and a second planarization layer 210 that are sequentially stacked. The light-emitting device layer 3 includes an anode layer 301, a pixel definition layer 302, a light-emitting layer 303 and a cathode layer 304 that are sequentially stacked. The encapsulation layer 4 includes a first support layer 305, a first inorganic encapsulation film layer 306, an organic encapsulation film layer 401, a second inorganic encapsulation film layer 402, a light-shielding layer 403 and a third planarization layer 404 that are sequentially stacked.

In some embodiments, as shown in FIGS. 3, 6 and 12, the opening edge region F further includes a wiring region F4 disposed on a side of the second isolation region F3 proximate to the display region AA, and a dimension d16, in the first direction X, of a portion of the light-shielding layer 403 in the first isolation region F1, the encapsulation region F2, the second isolation region F3 and the wiring region F4 is greater than or equal to 580 μm.

It will be noted that, the dimension d16 of the light-shielding layer 403 in the first direction X is a distance, in the first direction X, between a border line L4 of the light-shielding layer 403 proximate to the display region AA and a border line L5 of the light-shielding layer 403 proximate to the opening region H.

For example, as shown in FIGS. 3, 6 and 12, the opening edge region F includes the first isolation region F1, the encapsulation region F2, the second isolation region F3 and the wiring region F4 that are connected in sequence in the first direction X. The dimension d16, in the first direction X, of the light-shielding layer 403 disposed in the first isolation region F1, the encapsulation region F2, the second isolation region F3 and the wiring region F4 is 580 μm, 585 μm, 590 μm, 600 μm or 620 μm, which is not limited here. With such a design, the requirement for preventing light leakage in the opening edge region F may be met.

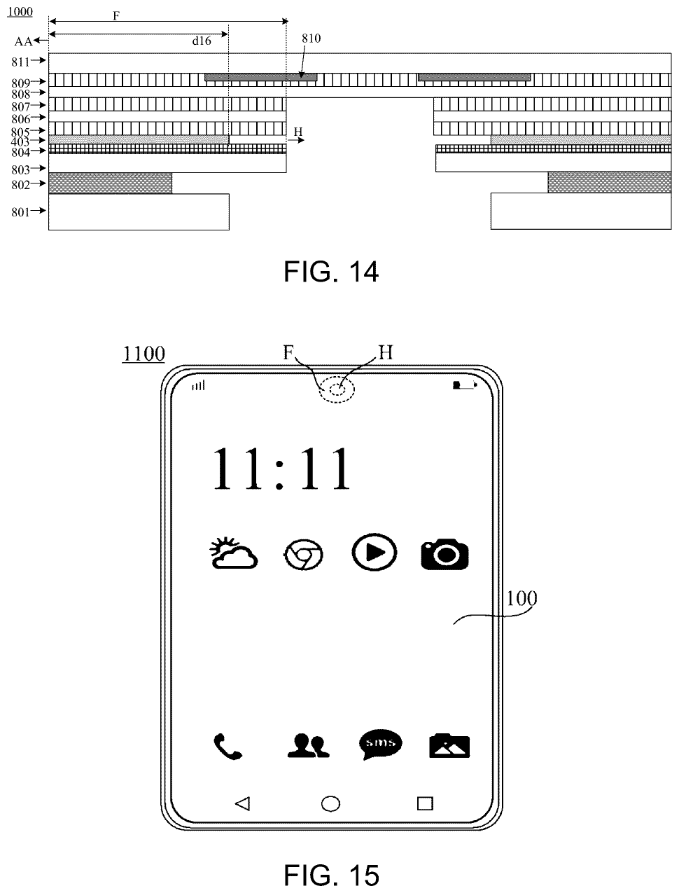

In some examples, when performing rainbow mura detection on the display panel 100 in the module process section, an example of a structure of the module 1000 is shown in FIG. 14, and the module 1000 includes: a second support layer 801, and a first buffer layer 802, a third support layer 803, a light-emitting panel 804, a light-shielding layer 403, a first protective layer adhesive 805, a first protective layer 806, a second protective layer adhesive 807, a second protective layer 808, a third protective layer adhesive 809, an ink light-shielding layer 810 and a third protective layer 811 that are disposed on the second support layer 801.

The light-emitting panel 804 and the light-shielding layer 403 may be understood as being used to indicate the position of the above-mentioned display panel 100 in the module 1000, or may be understood as the dimension requirement for the light-shielding layer 403 in the opening edge region F extending from the display region AA of the display panel 100 to the opening region H of the display panel 100.

In the related art, the polarizer technology, for example, is used, which requires that the dimension of the polarizer extending from the display region AA of the display panel 100 to the opening region H of the display panel is at least 580 μm, so as to meet the requirement for preventing light leakage. Therefore, in the embodiments of the present disclosure, the dimension d16, in the first direction X, of the light-shielding layer 403 in the first isolation region F1, the encapsulation region F2, the second isolation region F3 and the wiring region F4 is greater than or equal to 580 μm, which may meet the requirement for preventing light leakage.

In another aspect, as shown in FIG. 15, some embodiments of the present disclosure provide a display device 1100, and the display device 1100 includes the display panel 100 as described in any one of the above embodiments.

In some examples, the display device 1100 further includes a frame, a circuit board, a display driver integrated circuit (IC) and other electronic components. The display panel 100 is disposed in the frame.

The display device 1100 provided in the embodiments of the present disclosure may be any device that displays images whether in motion (e.g., videos) or stationary (e.g., static images) and whether textual or graphical. More specifically, it is expected that the embodiments may be implemented in or associated with various electronic devices, which include (but is not limit to), for example, a mobile phone, a wireless device, a personal digital assistant (PDA), a hand-held or portable computer, a GPS receiver/navigator, a camera, an MP4 video player, a video camera, a game console, a watch, a clock, a calculator, a TV monitor, a flat panel display, a computer monitor, a car display (e.g., an odometer display), a navigator, a cockpit controller and/or display, a display in camera view (e.g., a display for a rear camera in a vehicle), an electronic photo, an electronic billboard or indicator, a projector, building structures, packagings and aesthetic structures (e.g., a display for an image of a piece of jewelry).

The above are only specific embodiments of the present disclosure, but the protection scope of the present disclosure is not limited thereto, and variations or substitutions that any person skilled in the art may conceive of within the technical scope disclosed by the present disclosure, should fall within the protection scope of the present disclosure. Therefore, the protection scope of the present disclosure should be subjected to the protection scope of the claims.

1. A display panel, comprising: a display region, at least one opening region, and an opening edge region located between the opening region and the display region,
the opening edge region at least partially surrounding the opening region; wherein the opening edge region includes a first isolation region, an encapsulation region and a second isolation region that are sequentially arranged in a first direction, and the first direction is a direction from the opening region to the display region;
the display panel comprises a substrate and a light-shielding layer disposed on a side of the substrate;
wherein a ratio of an area of an orthographic projection of a portion of the light-shielding layer located in the first isolation region, the encapsulation region and the second isolation region to a sum of areas of the first isolation region, the encapsulation region and the second isolation region is in a range of 30% to 62%, inclusive.

2. The display panel according to claim 1, wherein the first isolation region includes a first light-shielding layer removal region disposed in the first isolation region and proximate to the opening region, and the first light-shielding layer removal region is provided with no light-shielding layer therein.

3. The display panel according to claim 2, wherein a dimension of the first light-shielding layer removal region in the first direction is in a range of 10 μm to 25 μm, inclusive.

4. The display panel according to claim 1, wherein the first isolation region includes a plurality of first isolation pillars arranged at intervals in the first direction, and each first isolation pillar of the plurality of first isolation pillars surrounds the opening region; and
the first isolation region includes a first light-shielding layer removal region, the first light-shielding layer removal region covers an orthographic projection of a first isolation pillar proximate to the opening region of the plurality of first isolation pillars on the substrate.

5. The display panel according to claim 1, wherein
the first isolation region includes a second light-shielding layer removal region disposed in the first isolation region and proximate to the encapsulation region; and
the second isolation region includes a third light-shielding layer removal region disposed in the second isolation region and proximate to the encapsulation region;
wherein the second light-shielding layer removal region, the encapsulation region and the third light-shielding layer removal region are provided with no light-shielding layer therein; and
the second light-shielding layer removal region, the encapsulation region and the third light-shielding layer removal region are sequentially connected in the first direction.

6. The display panel according to claim 5, wherein a sum of dimensions, in the first direction, of the second light-shielding layer removal region, the encapsulation region and the third light-shielding layer removal region is greater than or equal to 60 μm;
a dimension of the second light-shielding layer removal region in the first direction is in a range of 3 μm to 7 μm, inclusive;
a dimension of the third light-shielding layer removal region in the first direction is in a range of 30 μm to 60 μm, inclusive; and
a dimension of the encapsulation region in the first direction is in a range of 40 μm to 60 μm, inclusive.

7. The display panel according to claim 1, wherein a portion of the light-shielding layer located in the first isolation region, the encapsulation region and the second isolation region is provided with a plurality of first light-transmitting holes therein, and the plurality of first light-transmitting holes are arranged in an array in the first direction and a second direction; wherein
the second direction is a direction surrounding the opening region.

8. The display panel according to claim 7, wherein a dimension, in the first direction, of a region of the light-shielding layer where the plurality of first light-transmitting holes are disposed is in a range of 150 μm to 600 μm, inclusive.

9. The display panel according to claim 7, wherein
a dimension of each first light-transmitting hole of the plurality of first light-transmitting holes is in a range of 15 μm to 40 μm, inclusive;
a distance, in the first direction, between every two adjacent first light-transmitting holes of the plurality of first light-transmitting holes is in a range of 15 μm to 40 μm, inclusive; and
a distance, in the second direction, between every two adjacent first light-transmitting holes of the plurality of first light-transmitting holes is in a range of 15 μm to 40 μm, inclusive.

10. The display panel according to claim 1, wherein the opening edge region further includes a light-shielding layer bridge region, and the light-shielding layer bridge region overlaps the encapsulation region, a first portion of the first isolation region proximate to the encapsulation region, and a second portion of the second isolation region proximate to the encapsulation region; a portion of the light-shielding layer located in the light-shielding layer bridge region includes connection bridges and second light-transmitting holes that are alternately arranged in a second direction, wherein the second direction is a direction surrounding the opening region.

11. The display panel according to claim 10, wherein a dimension of the first portion in the first direction is in a range of 3 μm to 7 μm, inclusive, and a dimension of the second portion in the first direction is in a range of 30 μm to 60 μm, inclusive.

12. The display panel according to claim 10, wherein a ratio of a dimension, in the second direction, of a connection bridge of the connection bridges at a shortest position to a sum of dimensions, in the second direction, of the connection bridge at the shortest position and a second light-transmitting hole adjacent to the connection bridge at a shortest position is in a range of 40% to 62%, inclusive.

13. The display panel according to claim 12, wherein the dimension, in the second direction, of the connection bridge at the shortest position is greater than or equal to 30 μm; and
a dimension, in the second direction, of the second light-transmitting hole at the shortest position is less than or equal to 20 μm.

14. The display panel according to claim 10, wherein a dimension of the light-shielding layer bridge region in the first direction is greater than or equal to 60 μm.

15. The display panel according to claim 1, wherein the encapsulation region is provided with an encapsulation dam therein, and the encapsulation dam surrounds the opening region;
the first isolation region includes a plurality of first isolation pillars arranged at intervals in the first direction, and each first isolation pillar of the plurality of first isolation pillars surrounds the opening region; and
the second isolation region includes a plurality of second isolation pillars arranged at intervals in the first direction, and each second isolation pillar of the plurality of second isolation pillars surrounds the opening region.

16. The display panel according to claim 15, further comprising: at least one of a first source-drain metal layer and second source-drain metal layer, a first planarization layer, a second planarization layer and a first support layer that are disposed between the substrate and the light-shielding layer; wherein the at least one of the first source-drain metal layer and second source-drain metal layer, the first planarization layer, the second planarization layer and the first support layer are arranged in sequence in a third direction, and the third direction is a direction from the substrate to the light-shielding layer;
the first isolation pillars and the second isolation pillars are disposed in a same layer as the at least one of the first source-drain metal layer and second source-drain metal layer; and
the encapsulation dam includes a third portion, a fourth portion and a fifth portion that are sequentially stacked in the third direction; the third portion is disposed in a same layer as the first planarization layer, the fourth portion is disposed in a same layer as the second planarization layer, and the fifth portion is disposed in a same layer as the first support layer.

17. The display panel according to claim 16, further comprising: a first inorganic encapsulation film layer, an organic encapsulation film layer, a second inorganic encapsulation film layer and a third planarization layer that are disposed on a side of the first support layer away from the substrate; wherein the first inorganic encapsulation film layer, the organic encapsulation film layer, the second inorganic encapsulation film layer, the light-shielding layer and the third planarization layer are sequentially stacked in the third direction;
the third planarization layer overlaps the first isolation region, the encapsulation region and the second isolation region; and
in the second isolation region, the first inorganic encapsulation film layer, the organic encapsulation film layer and the second inorganic encapsulation film layer are sequentially arranged between the second isolation pillars and the light-shielding layer.

18. The display panel according to claim 15, further comprising: a first gate conductive layer and a second gate conductive layer that are disposed between the substrate and a first source-drain metal layer, wherein the first gate conductive layer and the second gate conductive layer are arranged in a third direction, and the third direction is a direction from the substrate to the light-shielding layer;
a first isolation pillar of the plurality of first isolation pillars and a second isolation pillar of the plurality of second isolation pillars are each provided with a first support portion and a second support portion on a side proximate to the substrate; the first support portion is disposed in a same layer as the first gate conductive layer, and the second support portion is disposed in a same layer as the second gate conductive layer.

19. The display panel according to claim 1, wherein the opening edge region further includes a wiring region disposed on a side of the second isolation region proximate to the display region, and a dimension, in the first direction, of a portion of the light-shielding layer in the first isolation region, the encapsulation region, the second isolation region and the wiring region is greater than or equal to 580 μm.

20. A display device, comprising the display panel according to claim 1.
